(19) United States
(12) Patent Application Publication
(10) Pub. No.: US 2021/0336087 A1
(43) Pub. Date: Oct. 28, 2021

(54) SEMICONDUCTOR LIGHT-EMITTING ELEMENT AND METHOD OF MANUFACTURING SEMICONDUCTOR LIGHT-EMITTING ELEMENT

(71) Applicant: NIKKISO CO., LTD., Tokyo (JP)

(72) Inventors: Tetsuhiko INAZU, Hakusan-shi (JP); Shinya FUKAHORI, Hakusan-shi (JP); Cyril PERNOT, Hakusan-shi (JP)

(21) Appl. No.: 17/235,648

(22) Filed: Apr. 20, 2021

(30) Foreign Application Priority Data
Apr. 24, 2020 (JP) 2020077634

(51) Int. Cl. H01L 33/32; H01L 33/38; H01L 33/00

(52) U.S. Cl. CPC H01L 33/32; H01L 2933/0016; H01L 33/0075; H01L 33/382

(57) ABSTRACT

A semiconductor light-emitting element includes: an n-type clad layer; an active layer; a p-type clad layer; a first p-type contact layer; a second p-type contact layer; and a p-side electrode. The AlN ratio of the p-type clad layer is 50% or higher. The first p-type contact layer has an AlN ratio of 5% or lower, has a p-type dopant concentration equal to or higher than 8×10¹⁸/cm³ and equal to or lower than 5×10¹⁹/cm³, and has a thickness larger than 500 nm. The second p-type contact layer has an AlN ratio of 5% or lower, has a p-type dopant concentration equal to or higher than 8×10¹⁹/cm³ and equal to or lower than 4×10²⁰/cm³, and has a thickness equal to or larger than 8 nm and equal to or smaller than 28 nm. The contact resistance of the p-side electrode is 1×10⁻² Ω·cm² or smaller.

### RELATED APPLICATION

Priority is claimed to Japanese Patent Application No. 2020-077634, filed on Apr. 24, 2020, the entire content of which is incorporated herein by reference.

### BACKGROUND OF THE INVENTION

### 1. Field of the Invention

The present invention relates to a semiconductor light-emitting element and a method of manufacturing a semiconductor light-emitting element.

### 2. Description of the Related Art

A light-emitting element for emitting deep ultraviolet light having a wavelength of 355 nm or shorter includes an AlGaN-based n-type clad layer, an active layer, and a p-type clad layer stacked on a substrate. A p-type contact layer made of p-type GaN is provided between the p-side electrode and the p-type clad layer to lower the contact resistance of the p-side electrode. The absorption coefficient of p-type GaN for deep ultraviolet light is high so that it is considered to be preferable to form the layer of p-type GaN to be thin from the perspective of securing light extraction efficiency. The thickness of the p-type contact layer is, for example, 300 nm or smaller or 50 nm or smaller (see, JP2014-96539A and WO2015/029281).

According to our knowledge, the life of a semiconductor light-emitting element is reduced if the thickness of the p-type contact layer is configured to be small.

### SUMMARY OF THE INVENTION

The present invention addresses the above-described issue, and an illustrative purpose thereof is to improve the life of a semiconductor light-emitting element.

A semiconductor light-emitting element according to an embodiment of the present embodiment includes: an n-type clad layer made of an n-type AlGaN-based semiconductor material; an active layer provided on the n-type clad layer and made of an AlGaN-based semiconductor material to emit deep ultraviolet light having a wavelength equal to or longer than 240 nm and equal to or shorter than 320 nm; a p-type clad layer provided on the active layer and made of a p-type AlGaN-based semiconductor material or a p-type AlN-based semiconductor material having an AlN ratio of 50% or higher; a first p-type contact layer provided in contact with the p-type clad layer and made of a p-type AlGaN-based semiconductor material or a p-type GaN-based semiconductor material having an AlN ratio of 5% or lower, the first p-type contact layer having a p-type dopant concentration equal to or higher than 8×10¹⁸/cm³ and equal to or lower than 5×10¹⁹/cm³ and having a thickness larger than 500 nm; a second p-type contact layer provided in contact with the first p-type contact layer and made of a p-type AlGaN-based semiconductor material or a p-type GaN-based semiconductor material having an AlN ratio of 5% or lower, the second p-type contact layer having a p-type dopant concentration equal to or higher than 8×10¹⁹/cm³ and equal to or lower than 4×10²⁰/cm³ and having a thickness equal to or larger than 8 nm and equal to or smaller than 28 nm; and a p-side electrode provided in contact with the second p-type contact layer such that contact resistance between the p-side electrode and the second p-type contact layer is 1×10⁻² Ω·cm² or smaller.

By providing the first p-type contact layer and the second p-type contact layer, with a low AlN composition, having an AlN ratio of 5% or lower, the contact resistance of the p-side electrode can be lowered, and the operating voltage of the semiconductor light-emitting element can be reduced. If the first p-type contact layer is directly formed on the p-type clad layer, with a high AlN composition, having an AlN ratio of 50% or lower, the lattice mismatch will be serious due to the large AlN ratio difference, and the first p-type contact layer will grow in the shape of an island on the p-type clad layer. If the thickness of the first p-type contact layer is small in this case, the flatness of the upper surface of the first p-type contact layer is reduced, and the element life is reduced. According to our knowledge, the flatness of the upper surface of the first p-type contact layer can be enhanced, and the element life can be improved considerably by configuring the thickness of the first p-type contact layer to be larger than 500 nm. Further, by configuring the second p-type contact layer in contact with the p-side electrode to have a p-type dopant concentration equal to or higher than 8×10¹⁹/cm³ and equal to or lower than 4×10²⁰/cm³ and have a thickness equal to or larger than 8 nm and equal to or smaller than 28 nm, the contact resistance of the p-side electrode can be 1×10⁻² Ω·cm² or smaller. By configuring the first p-type contact layer to have a p-type dopant concentration equal to or higher than 8×10¹⁸/cm³ and equal to or lower than 5×10¹⁹/cm³, the carrier mobility in the first p-type contact layer is increased, and the operating voltage of the semiconductor light-emitting element can be reduced.

The second p-type contact layer may have a p-type dopant concentration equal to or higher than 1×10²⁰/cm³ and equal to or lower than 2×10²⁰/cm³.

The second p-type contact layer may have a thickness equal to or larger than 11 nm and equal to or smaller than 20 nm.

The thickness of the first p-type contact layer may be equal to or larger than 700 nm and equal to or smaller than 1000 nm.

The p-type clad layer may be made of a p-type AlGaN-based semiconductor material having an AlN ratio of 60% or higher.

The first p-type contact layer and the second p-type contact layer may be made of p-type GaN.

Another embodiment of the present invention relates to a method of manufacturing a semiconductor light-emitting element. The method includes: forming an active layer made of an AlGaN-based semiconductor material on an n-type semiconductor layer made of an n-type AlGaN-based semiconductor material to emit deep ultraviolet light having a wavelength equal to or longer than 240 nm and equal to or shorter than 320 nm; forming, on the active layer, a p-type clad layer made of a p-type AlGaN-based semiconductor material or a p-type AlN-based semiconductor material having an AlN ratio of 50% or higher; forming a first p-type contact layer to be in contact with the p-type clad layer, the first p-type contact layer being made of a p-type AlGaN-based semiconductor material or a p-type GaN-based semiconductor material having an AlN ratio of 5% or lower, and the first p-type contact layer having a p-type dopant concentration equal to or higher than 8×10¹⁸/cm³ and equal to or lower than 5×10¹⁹/cm³ and having a thickness larger than 500 nm; forming a second p-type contact layer to be in contact with the first p-type contact layer, the second p-type contact layer being of a p-type AlGaN-based semiconductor material or a p-type GaN-based semiconductor material having an AlN ratio of 5% or lower, and the second p-type contact layer having a p-type dopant concentration equal to or higher than 8×10¹⁹/cm³ and equal to or lower than 4×10²⁰/cm³ and having a thickness equal to or larger than 8 nm and equal to or smaller than 28 nm; and forming a p-side electrode to be in contact with the second p-type contact layer such that contact resistance between the p-side electrode and the second p-type contact layer is 1×10⁻² Ω·cm² or smaller.

According to this embodiment, the same advantage as provided by the above embodiment can be provided.

A growth rate of the second p-type contact layer may be equal to or higher than 20% and equal to or lower than 60% of the growth rate of the first p-type contact layer.

### BRIEF DESCRIPTION OF THE DRAWINGS

FIG. 1 is a cross sectional view schematically showing a configuration of a semiconductor light-emitting element according to the embodiment;

FIG. 2 is a cross sectional view schematically showing a step of manufacturing the semiconductor light-emitting element;

FIG. 3 is a cross sectional view schematically showing a step of manufacturing the semiconductor light-emitting element;

FIG. 4 is a graph showing time-dependent change in the light emission intensity of the semiconductor light-emitting element according to the embodiment;

FIG. 5 is a graph showing a relationship between the life of the semiconductor light-emitting element according to the embodiment and the thickness of the first p-type contact layer;

FIG. 6 is a graph showing a relationship between the contact resistance of the p-side electrode and the dopant concentration of the second p-type contact layer;

FIG. 7 is a graph showing a relationship between the contact resistance of the p-side electrode and the thickness of the second p-type contact layer; and

FIG. 8 is a graph showing a relationship between the contact resistance of the p-side electrode and the dopant concentration/thickness of the second p-type contact layer.

### DETAILED DESCRIPTION OF THE INVENTION

The invention will now be described by reference to the preferred embodiments. This does not intend to limit the scope of the present invention, but to exemplify the invention.

A description will be given of an embodiment of the present invention with reference to the drawings. The same numerals are used in the description to denote the same elements, and a duplicate description is omitted as appropriate. To facilitate the understanding, the relative dimensions of the constituting elements in the drawings do not necessarily mirror the relative dimensions in the light-emitting element.

The embodiment relates to a semiconductor light-emitting element that is configured to emit “deep ultraviolet light” having a central wavelength λ of about 360 nm or shorter and is a so-called deep ultraviolet-light-emitting diode (DUV-LED) chip. To output deep ultraviolet light having such a wavelength, an aluminum gallium nitride (AlGaN)-based semiconductor material having a band gap of about 3.4 eV or larger is used. The embodiment particularly shows a case of emitting deep ultraviolet light having a central wavelength λ of about 240 nm-320 nm.

In this specification, the term “AlGaN-based semiconductor material” refers to a semiconductor material containing at least aluminum nitride (AlN) and gallium nitride (GaN) and shall encompass a semiconductor material containing other materials such as indium nitride (InN). Therefore, “AlGaN-based semiconductor materials” as recited in this specification can be represented by a composition In_{1-x-y}AlₓGa_{y}N (0<x+y≤1, 0<x<1, 0<y<1). The AlGaN-based semiconductor material shall encompass AlGaN or InAlGaN. The “AlGaN-based semiconductor material” in this specification has a molar fraction of AlN and a molar fraction of GaN of 1% or higher, and, preferably, 5% or higher, 10% or higher, or 20% or higher.

Those materials that do not contain AlN may be distinguished by referring to them as “GaN-based semiconductor materials”. “GaN-based semiconductor materials” include GaN or InGaN. Similarly, those materials that do not contain GaN may be distinguished by referring to them as “AlN-based semiconductor materials”. “AlN-based semiconductor materials” include AlN or InAlN.

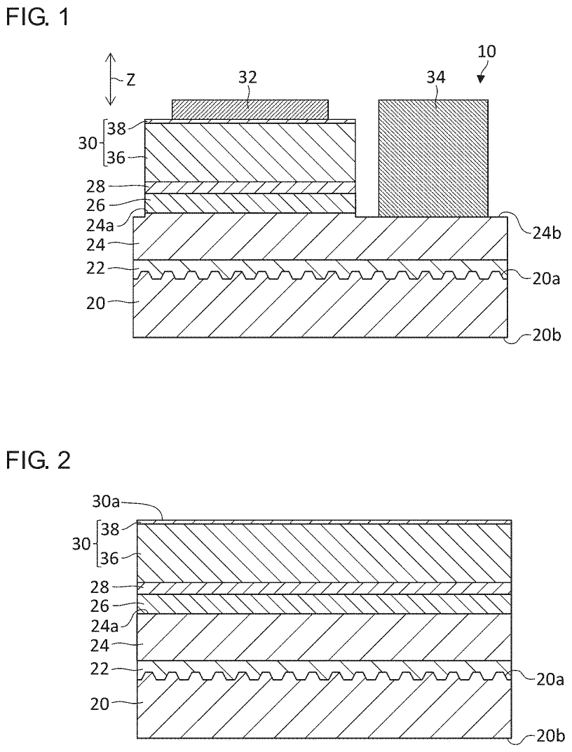

FIG. 1 is a cross sectional view schematically showing a configuration of a semiconductor light-emitting element 10 according to the embodiment. The semiconductor light-emitting element 10 includes a substrate 20, a base layer 22, an n-type clad layer 24, an active layer 26, a p-type clad layer 28, a p-type contact layer 30, a p-side electrode 32, and an n-side electrode 34.

Referring to FIG. 1, the direction indicated by the arrow Z may be referred to as “vertical direction” or “direction of thickness”. Further, as viewed from the substrate 20, the direction away from the substrate 20 may be defined as “upward”, and the direction toward the substrate 20 may be defined as “downward”.

The substrate 20 is a substrate having translucency for the deep ultraviolet light emitted by the semiconductor light-emitting element 10 and is, for example, a sapphire (Al₂O₃) substrate. The substrate 20 includes a first principal surface 20a and a second principal surface 20b opposite to the first principal surface 20a. The first principal surface 20a is a principal surface that is a crystal growth surface for growing the layers from the base layer 22 to the p-type contact layer 30. A fine concave-convex pattern having a submicron (1 μm or less) depth and pitch is formed on the first principal surface 20a. The substrate 20 like this is also called a patterned sapphire substrate (PSS). The second principal surface 20b is a principal surface that is a light extraction surface for extracting the deep ultraviolet light emitted by the active layer 26 outside. The substrate 20 may be an AlN substrate or an AlGaN substrate. The substrate 20 may be an ordinary substrate in which the first principal surface 20a is configured as a flat surface that is not patterned.

The base layer 22 is provided on the first principal surface 20a of the substrate 20. The base layer 22 is a foundation layer (template layer) to form the n-type clad layer 24. For example, the base layer 22 is an undoped AlN layer and is, specifically, an AlN layer grown at a high temperature (HT-AlN; High Temperature AlN). The base layer 22 may include an undoped AlGaN layer formed on the AlN layer. The base layer 22 may be comprised only of an undoped AlGaN layer when the substrate 20 is an AlN substrate or an AlGaN substrate. In other words, the base layer 22 includes at least one of an undoped AlN layer or an undoped AlGaN layer.

The n-type clad layer 24 is provided on the base layer 22. The n-type clad layer 24 is an n-type AlGaN-based semiconductor material layer. For example, the n-type clad layer 24 is an AlGaN layer doped with silicon (Si) as an n-type impurity. The composition ratio of the n-type clad layer 24 is selected to transmit the deep ultraviolet light emitted by the active layer 26. For example, the n-type clad layer 24 is formed such that the molar fraction of AlN is 40% or higher or 50% or higher. The n-type clad layer 24 has a band gap larger than the wavelength of the deep ultraviolet light emitted by the active layer 26. For example, the n-type clad layer 24 is formed to have a band gap of 3.85 eV or larger. It is preferable to form the n-type clad layer 24 such that the molar fraction of AlN is 80% or lower, i.e., the band gap is 5.5 eV or smaller. It is more preferable to form the n-type clad layer 24 such that the molar fraction of AlN is 70% or lower (i.e., the band gap is 5.2 eV or smaller). The n-type clad layer 24 has a thickness of about 1 μm-3 μm. For example, the n-type clad layer 24 has a thickness of about 2 μm.

The n-type clad layer 24 is formed such that the concentration of Si as the impurity is equal to or higher than 1×10¹⁸/cm³ and equal to or lower than 5×10¹⁹/cm³. It is preferred to form the n-type clad layer 24 such that the Si concentration is equal to or higher than 5×10¹⁸/cm³ and equal to or lower than 3×10¹⁹/cm³, and, more preferably, equal to or higher than 7×10¹⁸/cm³ and equal to or lower than 2×10¹⁹/cm³. In one example, the Si concentration in the n-type clad layer 24 is around 1×10¹⁹/cm³ and is in a range equal to or higher than 8×10¹⁸/cm³ and equal to or lower than 1.5×10¹⁹/cm³.

The n-type clad layer 24 includes a first upper surface 24a and a second upper surface 24b. The first upper surface 24a is where the active layer 26 is formed. The second upper surface 24b is where the active layer 26 is not formed, and the n-side electrode 34 is formed.

The active layer 26 is provided on the first upper surface 24a of the n-type clad layer 24. The active layer 26 is made of an AlGaN-based semiconductor material and has a double heterojunction structure by being sandwiched between the n-type clad layer 24 and the p-type clad layer 28. To output deep ultraviolet light having a wavelength of 355 nm or shorter, the active layer 26 is formed to have a band gap of 3.4 eV or larger. For example, the AlN composition ratio of the active layer 26 is selected so as to output deep ultraviolet light having a wavelength of 320 nm or shorter.

The active layer 26 may have, for example, a monolayer or multilayer quantum well structure. The active layer 26 is comprised of a stack of a barrier layer made of an undoped AlGaN-based semiconductor material and a well layer made of an undoped AlGaN-based semiconductor material. The active layer 26 includes, for example, a first barrier layer directly in contact with the n-type clad layer 24 and a first well layer provided on the first barrier layer. One or more pairs of the well layer and the barrier layer may be additionally provided between the first barrier layer and the first well layer. The barrier layer and the well layer have a thickness of about 1 nm-20 nm, and have a thickness of, for example, about 2 nm-10 nm.

The active layer 26 may further include an electron blocking layer directly in contact with the p-type clad layer 28. The electron blocking layer is an undoped AlGaN-based semiconductor material layer and is formed such that the molar fraction of AlN is 80% or higher. The electron blocking layer may be made of an AlN-based semiconductor material that does not substantially contain GaN. The electron blocking layer has a thickness of about 1 nm-10 nm. For example, the electron blocking layer has a thickness of about 2 nm-5 nm.

The p-type clad layer 28 is formed on the active layer 26. The p-type clad layer 28 is a p-type AlGaN-based semiconductor material layer. For example, the p-type clad layer 28 is an AlGaN layer doped with magnesium (Mg) as a p-type impurity. The p-type clad layer 28 is a high-AlN composition layer (also referred to as a first AlN composition layer) having a relatively high AlN ratio as compared with the p-type contact layer 30. The p-type clad layer 28 is formed such that the molar fraction of AlN is 50% or higher, and, preferably, 60% or higher, or 70% or higher. The p-type clad layer 28 has a thickness of about 10 nm-100 nm and has a thickness of, for example, about 15 nm-70 nm.

The p-type contact layer 30 is formed on the p-type clad layer 28 and is in direct contact with the p-type clad layer 28. The p-type contact layer 30 is a p-type AlGaN-based semiconductor material layer or a p-type GaN-based semiconductor material layer. The p-type contact layer 30 is a low-AlN composition layer (also referred to as a second AlN composition layer) having a relatively low AlN ratio as compared with the p-type clad layer 28. The difference between the AlN ratio of the p-type contact layer 30 and the AlN ratio of the p-type clad layer 28 is 50% or higher, and, preferably, 60% or higher. The p-type contact layer 30 is configured such that the AlN ratio is 20% or lower in order to obtain proper ohmic contact with the p-side electrode 32. Preferably, the p-type contact layer 30 is formed such that the AlN ratio is 10% or lower, 5% or lower, or 0%. In other words, the p-type contact layer 30 may be a p-type GaN layer that does not substantially contain AlN. As a result, the p-type contact layer 30 could absorb the deep ultraviolet light emitted by the active layer 26.

The p-type contact layer 30 includes a first p-type contact layer 36 and a second p-type contact layer 38. The first p-type contact layer 36 is in direct contact with the p-type clad layer 28. The first p-type contact layer 36 is configured such that the AlN ratio is 20% or lower. Preferably, the first p-type contact layer 36 is formed such that the AlN ratio is 10% or lower, 5% or lower, or 0%. The first p-type contact layer 36 has a thickness in excess of 500 nm. For example, the first p-type contact layer 36 has a thickness of 520 nm or larger. The first p-type contact layer 36 preferably has a thickness in excess of 590 nm. For example, the first p-type contact layer 36 has a thickness equal to or larger than 700 nm and equal to or smaller than 1000 nm. The p-type dopant concentration of the first p-type contact layer 36 is in a range equal to or higher than 8×10¹⁸/cm³ and equal to or lower than 5×10¹⁹/cm³, and, preferably, in a range equal to or higher than 1×10¹⁹/cm³ and equal to or lower than 2×10¹⁹/cm³. By configuring the p-type dopant concentration of the first p-type contact layer 36 to have such a value, the carrier mobility in the first p-type contact layer 36 is increased, and the bulk resistance of the first p-type contact layer 36 having a large thickness is reduced.

The second p-type contact layer 38 is provided on the first p-type contact layer 36 and is in direct contact with the first p-type contact layer 36. The second p-type contact layer 38 is configured such that the AlN ratio is 20% or lower. Preferably, the second p-type contact layer 38 is formed such that the AlN ratio is 10% or lower, 5% or lower, or 0%. The AlN ratio of the second p-type contact layer 38 may be equal to the AlN ratio of the first p-type contact layer 36 or lower than the AlN ratio of the first p-type contact layer 36. In the case the AlN ratio of the first p-type contact layer 36 exceeds 0% and is 10% or lower, the AlN ratio of the second p-type contact layer 38 may be 0%. The second p-type contact layer 38 has a thickness equal to or larger than 8 nm and equal to or smaller than 28 nm, and, preferably, equal to or larger than 9 nm and equal to or smaller than 25 nm, and, more preferably, equal to or larger than 11 nm and equal to or smaller than 20 nm. The second p-type contact layer 38 may have a thickness of about 16 nm. The p-type dopant concentration of the second p-type contact layer 38 is higher than the p-type dopant concentration of the first p-type contact layer 36 and about 5-20 times the p-type dopant concentration of the first p-type contact layer 36. The second p-type contact layer 38 has a p-type dopant concentration equal to or higher than 8×10¹⁸/cm³ and equal to or lower than 5×10¹⁹/cm³, and, preferably, equal to or higher than 1×10²⁰/cm³ and equal to or lower than 2×10²⁰/cm³. By configuring the p-type dopant concentration of the second p-type contact layer 38 to have such a value, the contact resistance of the p-side electrode 32 can be 1×10⁻² Ω·cm² or smaller, and, more preferably, 1×10⁻³ Ω·cm² or smaller.

The p-side electrode 32 is provided on the p-type contact layer 30 and is in ohmic contact with the p-type contact layer 30. More specifically, the p-side electrode 32 is in direct contact with the second p-type contact layer 38. The p-side electrode 32 is configured such that the contact resistance between the p-side electrode 32 and the p-type contact layer 30 is 1×10⁻² Ω·cm² or smaller. The embodiment is non-limiting as to the material of the p-side electrode 32. For example, the p-side electrode 32 is made of a transparent conductive oxide such as indium tin oxide (ITO), a platinum group metal such as rhodium (Rh), or a stack structure of nickel and gold (Ni/Au).

The n-side electrode 34 is provided on the second upper surface 24b of the n-type clad layer 24. The n-side electrode 34 is made of a material that can be in ohmic contact with the n-type clad layer 24 and has a high reflectivity for the deep ultraviolet light emitted by the active layer 26. The embodiment is non-limiting as to the material of the n-side electrode 34. For example, the n-side electrode 34 is comprised of a Ti layer directly in contact with the n-type clad layer 24 and an Al layer directly in contact with the Ti layer.

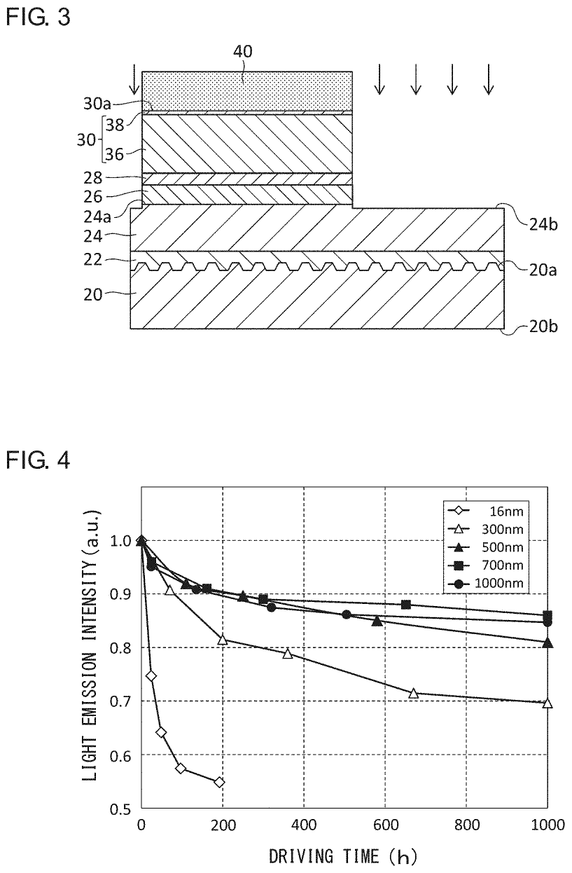

A description will now be given of a method of manufacturing the semiconductor light-emitting element 10 with reference to FIG. 2 and FIG. 3. First, as shown in FIG. 2, the base layer 22, the n-type clad layer 24, the active layer 26, the p-type clad layer 28, the first p-type contact layer 36, and the second p-type contact layer 38 are formed on the first principal surface 20a of the substrate 20 successively. The base layer 22, the n-type clad layer 24, the active layer 26, the first p-type contact layer 36, and the second p-type contact layer 38 can be formed by a well-known epitaxial growth method such as the metalorganic chemical vapor deposition (MOVPE) method and the molecular beam epitaxial (MBE) method.

The first p-type contact layer 36 is directly formed on the p-type clad layer 28. The difference between the AlN ratio of the p-type clad layer 28 and the AlN ratio of the first p-type contact layer 36 is 50% or higher so that the lattice mismatch difference at the interface between the p-type clad layer 28 and the first p-type contact layer 36 is very serious. For this reason, the first p-type contact layer 36 grows on the p-type clad layer 28 in the shape of an island (so-called island growth). In the case island growth takes place, the thickness of the portion at which crystal growth starts will be relatively large, and the thickness of the portion distanced from the portion of start will be relatively small. Therefore, the concave-convex structure remains on the upper surface of the semiconductor layer on which crystal growth has taken place, which is likely to result in a less flat surface. According to our knowledge, the larger the thickness of the first p-type contact layer 36, the more improved the flatness of the upper surface 30a of the p-type contact layer 30. By growing the first p-type contact layer 36 to a thickness in excess of 500 nm, in particular, the flatness of the upper surface 30a of the p-type contact layer 30 is significantly improved.

The second p-type contact layer 38 is directly formed on the first p-type contact layer 36. The second p-type contact layer 38 has a higher p-type dopant concentration, and, more specifically, a higher Mg dopant concentration, than the first p-type contact layer 36. The growth rate of the second p-type contact layer 38 is lower than the growth rate of the first p-type contact layer 36 and is equal to or higher than 20% and equal to or lower than 60% of the growth rate of the first p-type contact layer 36. For example, the growth rate of the first p-type contact layer 36 is about 1 μm/minute-1.3 μm/minute, but the growth rate of the second p-type contact layer 38 is about 0.3 μm/minute-0.6 μm/minute. By lowering the growth rate of the second p-type contact layer 38, the dopant concentration of the second p-type contact layer 38 is suitably increased. For example, the growth rate of the second p-type contact layer 38 can be lowered and the dopant concentration thereof can be increased, by lowering the rate of supplying trimethylgallium (TMGa) and/or trimethylaluminum (TMA), while maintaining a constant rate of supplying bis cyclopentadienyl magnesium (Cp₂Mg), which is a raw material for the p-type dopant.

Next, as shown in FIG. 3, a mask 40 is formed in a partial region on the p-type contact layer 30, and the mask 40 is dry-etched from above. The mask 40 can be formed by using, for example, a publicly known photolithographic technology. The dry-etching removes the p-type contact layer 30, the p-type clad layer 28, and the active layer 26 in the region in which the mask 40 is not formed. The dry-etching is performed until the n-type clad layer 24 is exposed in the region in which the mask 40 is not formed. In this way, the second upper surface 24b of the n-type clad layer 24 is formed. The mask 40 is removed after the dry-etching is performed.

Subsequently, the n-side electrode 34 is formed on the second upper surface 24b of the n-type clad layer 24, and the n-side electrode 34 is annealed. Subsequently, the p-side electrode 32 is formed on the upper surface 30a of the p-type contact layer 30, and the p-side electrode 32 is annealed. The embodiment is non-limiting as to the sequence of formation of the p-side electrode 32 and the n-side electrode 34 or the timing of annealing. For example, the p-side electrode 32 may be formed first, and then the n-side electrode 34 may be formed. This completes the semiconductor light-emitting element 10 shown in FIG. 1.

According to this embodiment, the flatness of the upper surface 30a of the p-type contact layer 30 is improved by configuring the thickness of the p-type contact layer 30 to be large. By forming the p-side electrode 32 on the highly flat upper surface 30a, the in-plane uniformity of the density of the current flowing toward the active layer 26 through the p-side electrode 32 is enhanced. Stated otherwise, it prevents the current from being locally concentrated and the current density from becoming uneven within the plane due to the concave-convex structure at the interface between the p-type contact layer 30 and the p-side electrode 32. This prevents the impact of reduced element life resulting from an excessive current flowing in a portion of the semiconductor light-emitting element 10.

In the related art, it has been considered to be preferable in a semiconductor light-emitting element for emitting deep ultraviolet light having a wavelength of 320 nm or shorter to reduce the thickness of the p-type contact layer 30 as much as possible in order to avoid absorption of deep ultraviolet light by the p-type contact layer 30. More specifically, it has been considered preferable to configure the thickness of a p-type GaN layer to be 300 nm or smaller or 50 nm or smaller. Meanwhile, we have found that the flatness of the upper surface 30a of the p-type contact layer 30 is greatly improved by enlarging the thickness of the p-type contact layer 30 to the extent that it is in excess of 500 nm. According to this embodiment, significant advantages described below are achieved by configuring the thickness of the p-type contact layer 30 to be larger than 500 nm.

FIG. 4 is a graph showing time-dependent change in the light emission intensity of the semiconductor light-emitting element according to the embodiment. FIG. 4 shows the light emission intensity of the semiconductor light-emitting element 10 that results when the thickness of the first p-type contact layer 36 is 16 nm, 300 nm, 500 nm, 700 nm, and 1000 nm. In the embodiment, the wavelength of light emitted by the active layer 26 is about 280 nm-285 nm, the AlN ratio of the p-type clad layer 28 is 75%, and the AlN ratio of the p-type contact layer 30 is 0%. The AlN ratio of the n-type clad layer 24 is 55%. Referring to FIG. 4, the light emission intensity at the start of lighting of the light-emitting element is defined to be 1.

As shown in FIG. 4, it is known that the smaller the thickness of the first p-type contact layer 36, the larger the speed of reduction in the light emission intensity. The light emission intensity that results when the thickness of the first p-type contact layer 36 is 16 nm drops to 75% after 24 hours and drops to 70% after 48 hours. The light emission intensity that results when the thickness of the first p-type contact layer 36 is 300 nm drops to 81% after 200 hours and drops to 70% after 950 hours. On the other hand, the light emission intensity that results when the thickness of the first p-type contact layer 36 is 500 nm is 90% or higher after 200 hours and is 80% or higher after 1000 hours. Similarly, the light emission intensity that results when the thickness of the first p-type contact layer 36 is 700 nm is 90% or higher after 200 hours and is 85% or higher after 1000 hours. Further, the light emission intensity that results when the thickness of the first p-type contact layer 36 is 1000 nm is about 90% or higher after 200 hours and is about 85% after 1000 hours. Thus, enlarging the thickness of the first p-type contact layer 36 can slow down reduction in the light emission intensity and extend the time for which the light emission intensity of a certain level or higher can be maintained, i.e., the element life.

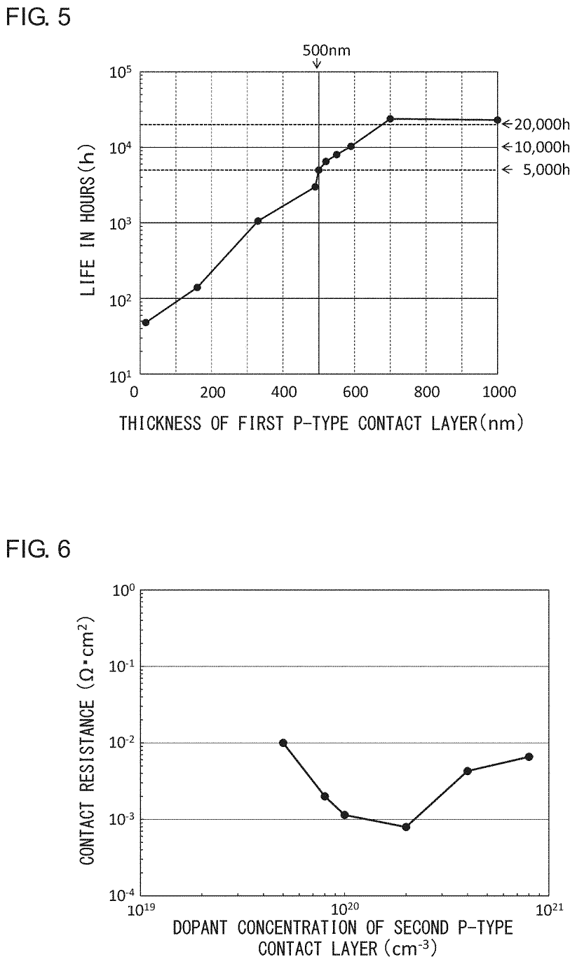

FIG. 5 is a graph showing a relationship between the life of the semiconductor light-emitting element 10 according to the embodiment and the thickness of the first p-type contact layer 36. In FIG. 5, the time elapsed until the light emission intensity of the semiconductor light-emitting element 10 drops to 70% is defined as the life. As shown in the figure, the larger the thickness of the first p-type contact layer 36, the longer the element life. The graph shows that the element life is significantly extended when the thickness of the first p-type contact layer 36 exceeds 500 nm. More specifically, the element life exceeds 5000 hours when the thickness of the first p-type contact layer 36 exceeds 500 nm. The element life that results when the thickness of the first p-type contact layer 36 is 520 nm is 6500 hours, and the element life that results when the thickness of the first p-type contact layer 36 is 550 nm is 8000 hours. Further, when the thickness of the first p-type contact layer 36 is 590 nm or larger, the element life will be 10000 hours or longer. Still further, the element life of 20000 hours or longer can be realized when the thickness of the first p-type contact layer 36 is equal to or larger than 700 nm and equal to or smaller than 1000 nm.

It is also possible to configure the thickness of the first p-type contact layer 36 to be larger than 1000 nm. For example, a suitable element life of 10000 hours or longer can be realized by configuring the thickness of the first p-type contact layer 36 to be 1500 nm or 2000 nm. If the thickness of the first p-type contact layer 36 is enlarged, however, the time required to grow the first p-type contact layer 36 in the step of FIG. 2 is extended with the result that the time required to dry-etch the first p-type contact layer 36 in the step of FIG. 3 is also extended. Further, if the thickness of the first p-type contact layer 36 is large, the difference between the height of the upper surface 30a of the p-type contact layer 30 and the height of the second upper surface 24b of the n-type clad layer 24 will be large.

In order to reduce defects during packaging of the semiconductor light-emitting element 10, it is necessary to align the heights of the p-side electrode 32 and the n-side electrode 34. This requires enlarging the thickness of the n-side electrode 34. It will then increase the time required to form the n-side electrode 34 and the material cost. From these perspectives, it is preferred to configure the thickness of the first p-type contact layer 36 to be 1000 nm or smaller.

In further accordance with this embodiment, the contact resistance of the p-side electrode 32 relative to the second p-type contact layer 38 is suitably reduced by properly setting the dopant concentration of the first p-type contact layer 36 and the second p-type contact layer 38. Generally, the higher the dopant concentration of the p-type contact layer 30, the smaller the contact resistance of the p-side electrode 32. If the dopant concentration of the p-type contact layer 30 is too high, however, drop in the activation rate of the p-type dopant increases a portion that does not function as carriers (holes) effectively and produces excessive doping. As a result, the carrier mobility in the p-type contact layer 30 tends to be lowered. In accordance with this embodiment, the bulk resistance of the p-type contact layer 30 as a whole is reduced by configuring the dopant concentration of the first p-type contact layer 36 having a large thickness to be within a proper range to avoid excessive doping in the first p-type contact layer 36. Further, the smaller thickness of the second p-type contact layer 38, which has a higher dopant concentration than the first p-type contact layer 36, suppresses increase in the bulk resistance of the p-type contact layer 30 as a whole and, at the same time, improves the contact resistance of the_{A}-side electrode 32.

According to this embodiment, the contact resistance of the p-type contact layer 30 can be 1×10⁻² Ω·cm² or smaller, and, more preferably, 1×10⁻³ Ω·cm² or smaller by properly setting the dopant concentration and thickness of the second p-type contact layer 38. The preferable dopant concentration and thickness of the second p-type contact layer 38 will be described with reference to FIGS. 6-8.

FIG. 6 is a graph showing a relationship between the contact resistance of the p-side electrode 32 and the dopant concentration of the second p-type contact layer 38. Referring to FIG. 6, the thickness of the second p-type contact layer 38 is fixed to 10 nm, and the dopant concentration of the second p-type contact layer 38 is made to vary in a range 5×10¹⁹/cm³-8×10¹⁹/cm³. As illustrated, the contact resistance of 1×10⁻² Ω·cm² or smaller is realized in the range 8×10¹⁹/cm³-8×10²⁰/cm³. It is also known that the contact resistance is reduced to about 1×10⁻³ Ω·cm² when the dopant concentration of the second p-type contact layer 38 is about 1×10²⁰/cm³-2×10²⁰/cm³.

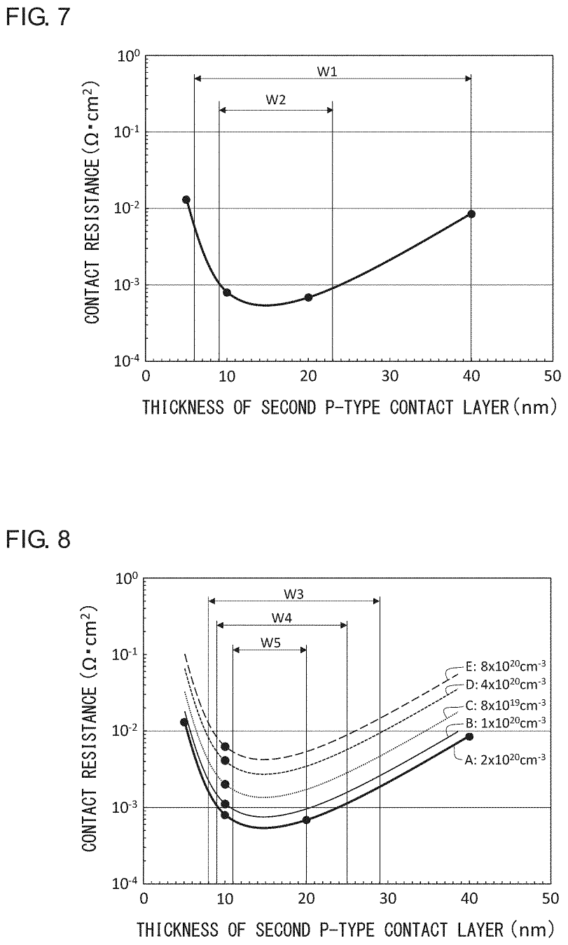

FIG. 7 is a graph showing a relationship between the contact resistance of the p-side electrode 32 and the thickness of the second p-type contact layer 38. Referring to FIG. 7, the dopant concentration of the second p-type contact layer 38 is fixed to 2×10²⁰/cm³, and the thickness of the second p-type contact layer 38 is made to vary in a range 5 nm-40 nm. As illustrated, it is considered that the contact resistance of 1×10⁻² Ω·cm² or smaller is realized in a range W1 in which the thickness of the second p-type contact layer 38 is 6 nm-40 nm. Further, it is considered that the contact resistance of 1×10⁻³ Ω·cm² or smaller is realized in a range W2 in which the thickness of the second p-type contact layer 38 is 9 nm-23 nm.

FIG. 8 is a graph showing a relationship between the contact resistance of the p-side electrode 32 and the dopant concentration/thickness of the second p-type contact layer 38. FIG. 8 is a combination of the graphs of FIG. 6 and FIG. 7. The curve A of FIG. 8 is the same as the curve of FIG. 7. The curves B-E of FIG. 8 are produced by parallel shift of the curve A with reference to the data of FIG. 6, in which the thickness is fixed to 10 nm. The plots shown in the graph of FIG. 8 correspond to the plots shown in FIG. 6 or FIG. 7.

As shown in FIG. 8, it is considered that, in a range W3 in which the thickness of the second p-type contact layer 38 is 8 nm-28 nm, the contact resistance of 1×10⁻² Ω·cm² or smaller is realized provided that the dopant concentration of the second p-type contact layer 38 is equal to or higher than 8×10¹⁹/cm³ and equal to or lower than 4×10²⁰/cm³. Further, it is considered that, in a range W4 in which the thickness of the second p-type contact layer 38 is 9 nm-25 nm, the contact resistance of 1×10⁻² Ω·cm² or smaller is realized provided that the dopant concentration of the second p-type contact layer 38 is equal to or higher than 8×10¹⁹/cm³ and equal to or lower than 8×10²⁰/cm³. Still further, it is considered that, in a range W5 in which the thickness of the second p-type contact layer 38 is 11 nm-20 nm, the contact resistance of 1×10⁻³ Ω·cm² or smaller is realized provided that the dopant concentration of the second p-type contact layer 38 is equal to or higher than 1×10²⁰/cm³ and equal to or lower than 2×10²⁰/cm³.

Described above is an explanation based on an exemplary embodiment. The embodiment is intended to be illustrative only and it will be understood by those skilled in the art that various design changes are possible and various modifications are possible and that such modifications are also within the scope of the present invention.

In an alternative embodiment, the p-type clad layer 28 may be comprised of a plurality of p-type semiconductor layers having different AlN ratios. The p-type clad layer 28 may, for example, include a p-type first semiconductor layer in contact with the p-type contact layer 30 and a p-type second semiconductor layer provided between the active layer 26 and the p-type first semiconductor layer. The p-type first semiconductor layer in contact with the p-type contact layer 30 is made of a p-type AlGaN-based semiconductor material having an AlN ratio that differs from that of the p-type contact layer 30 by 50% or more. The p-type second semiconductor layer is made of a p-type AlGaN-based semiconductor material or a p-type AlN-based semiconductor material having an AlN ratio higher than that of the p-type first semiconductor layer.

In a further alternative embodiment, the AlN ratio of the p-type clad layer 28 may be configured to vary in the direction of thickness. The AlN ratio of the p-type clad layer 28 may be configured to be progressively smaller in the direction from the active layer 26 toward the p-type contact layer 30. In this case, an upper surface 28a of the p-type clad layer 28 is configured such that the AlN ratio difference from the p-type contact layer 30 is 50% or more.

In a still further embodiment, an arbitrary AlGaN-based semiconductor layer or an AlN-based semiconductor material layer may be additionally provided between the active layer 26 and the p-type clad layer 28. The semiconductor material layer provided between the active layer 26 and the p-type clad layer 28 may be a p-type layer or an undoped layer.

What is claimed is:

1. A semiconductor light-emitting element comprising:
an n-type clad layer made of an n-type AlGaN-based semiconductor material;
an active layer provided on the n-type clad layer and made of an AlGaN-based semiconductor material to emit deep ultraviolet light having a wavelength equal to or longer than 240 nm and equal to or shorter than 320 nm;
a p-type clad layer provided on the active layer and made of a p-type AlGaN-based semiconductor material or a p-type AlN-based semiconductor material having an AlN ratio of 50% or higher;
a first p-type contact layer provided in contact with the p-type clad layer and made of a p-type AlGaN-based semiconductor material or a p-type GaN-based semiconductor material having an AlN ratio of 5% or lower, the first p-type contact layer having a p-type dopant concentration equal to or higher than 8×10¹⁸/cm³ and equal to or lower than 5×10¹⁹/cm³ and having a thickness larger than 500 nm;
a second p-type contact layer provided in contact with the first p-type contact layer and made of a p-type AlGaN-based semiconductor material or a p-type GaN-based semiconductor material having an AlN ratio of 5% or lower, the second p-type contact layer having a p-type dopant concentration equal to or higher than 8×10¹⁹/cm³ and equal to or lower than 4×10²⁰/cm³ and having a thickness equal to or larger than 8 nm and equal to or smaller than 28 nm; and
a p-side electrode provided in contact with the second p-type contact layer such that contact resistance between the p-side electrode and the second p-type contact layer is 1×10⁻² Ω·cm² or smaller.

2. The semiconductor light-emitting element according to claim 1, wherein
the second p-type contact layer has a p-type dopant concentration equal to or higher than 1×10²⁰/cm³ and equal to or lower than 2×10²⁰/cm³.

3. The semiconductor light-emitting element according to claim 1, wherein
the second p-type contact layer has a thickness equal to or larger than 11 nm and equal to or smaller than 20 nm.

4. The semiconductor light-emitting element according to claim 1, wherein
the thickness of the first p-type contact layer is equal to or larger than 700 nm and equal to or smaller than 1000 nm.

5. The semiconductor light-emitting element according to claim 1, wherein
the p-type clad layer is made of a p-type AlGaN-based semiconductor material having an AlN ratio of 60% or higher.

6. The semiconductor light-emitting element according to claim 1, wherein
the first p-type contact layer and the second p-type contact layer are made of p-type GaN.

7. A method of manufacturing a semiconductor light-emitting element, comprising:
forming an active layer made of an AlGaN-based semiconductor material on an n-type semiconductor layer made of an n-type AlGaN-based semiconductor material to emit deep ultraviolet light having a wavelength equal to or longer than 240 nm and equal to or shorter than 320 nm;
forming, on the active layer, a p-type clad layer made of a p-type AlGaN-based semiconductor material or a p-type AlN-based semiconductor material having an AlN ratio of 50% or higher;
forming a first p-type contact layer to be in contact with the p-type clad layer, the first p-type contact layer being made of a p-type AlGaN-based semiconductor material or a p-type GaN-based semiconductor material having an AlN ratio of 5% or lower, and the first p-type contact layer having a p-type dopant concentration equal to or higher than 8×10¹⁸/cm³ and equal to or lower than 5×10¹⁹/cm³ and having a thickness larger than 500 nm;
forming a second p-type contact layer to be in contact with the first p-type contact layer, the second p-type contact layer being of a p-type AlGaN-based semiconductor material or a p-type GaN-based semiconductor material having an AlN ratio of 5% or lower, and the second p-type contact layer having a p-type dopant concentration equal to or higher than 8×10¹⁹/cm³ and equal to or lower than 4×10²⁰/cm³ and having a thickness equal to or larger than 8 nm and equal to or smaller than 28 nm; and
forming a p-side electrode to be in contact with the second p-type contact layer such that contact resistance between the p-side electrode and the second p-type contact layer is 1×10⁻² Ω·cm² or smaller.

8. The method of manufacturing a semiconductor light-emitting element according to claim 7, wherein
a growth rate of the second p-type contact layer is equal to or higher than 20% and equal to or lower than 60% of the growth rate of the first p-type contact layer.
